(19) United States
(12) Patent Application Publication
(10) Pub. No.: US 2016/0172276 A1
(43) Pub. Date: Jun. 16, 2016

(54) Bonding clip, carrier and method of manufacturing a bonding clip

(71) Applicant: Infineon Technologies AG, Neubiberg (DE)

(72) Inventors: Xavier AROKIASAMY, Perak (MY); Sim Fah LEONG, Seremban (MY)

(21) Appl. No.: 14/967,271

(22) Filed: Dec. 12, 2015

(30) Foreign Application Priority Data
Dec. 15, 2014 (DE) 10 2014 118 628.1

(51) Int. Cl. H01L 23/495; H01L 21/48

(52) U.S. Cl. CPC H01L 23/49548; H01L 21/4842; H01L 21/4828

(57) ABSTRACT

Various embodiments provide a clip for clip bonding of a die to a carrier (bonding clip), wherein the clip comprises a clip body comprising a first region configured to be fixed on a carrier and a second region configured to be fixed to a die, wherein at least one of the first region and the second region comprises a guiding structure configured to guide the clip when connecting the carrier and the die.

### TECHNICAL FIELD

Various embodiments relate to bonding clip, a carrier for a semiconductor component, and a method of manufacturing a bonding clip.

### BACKGROUND

In the field of manufacturing semiconductor components the use of clip bonds to electrically connect the semiconductor die to a metal lead frame is known.

For example, from US2002066963 A1 a semiconductor package or semiconductor component is known, wherein the semiconductor component comprises a semiconductor chip, an electrically conductive adhesive located over the semiconductor chip, and a clip bond located over the electrically conductive adhesive and the semiconductor chip. The clip bond has at least one burr. The clip bond can also include at least one hole, notch, or via located over the electrically conductive adhesive. The burr or burrs are located adjacent to a perimeter of each of the hole or holes such that the configuration of the hole or holes and the burr or burrs retain or hold the electrically conductive adhesive in place, even when the electrically conductive adhesive is melted.

### SUMMARY

Various embodiments provide a clip for clip bonding of a die to a carrier (bonding clip), wherein the clip comprises a clip body comprising a first region configured to be fixed on a carrier and a second region configured to be fixed to a die, wherein at least one of the first region and the second region comprises a guiding structure configured to guide the clip when connecting the carrier and the die.

Furthermore, various embodiments provide a carrier for a semiconductor component, wherein the carrier comprises a carrier body comprising a first region configured to be fixed to a clip, wherein the first region comprises a guiding element configured to guide the clip when connecting the clip to the carrier.

Moreover, various embodiments provide a method of manufacturing a bonding clip, wherein the method comprises: providing a clip body comprising a first region configured to be fixed on a carrier and a second region configured to be fixed to a die, and forming a guiding structure in at least one of the first region and the second region, wherein the guiding structure is configured to guide the clip when connecting the carrier and the die.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A to 1E schematically illustrate a semiconductor component in various processing steps;

FIGS. 2A to 2E schematically illustrate a semiconductor component in various processing steps;

FIGS. 3A to 3B schematically illustrate a method of manufacturing a bonding clip;

FIGS. 4A to 4C schematically illustrate a method of manufacturing a bonding clip; and

FIGS. 5A to 5B schematically illustrate a method of manufacturing a bonding clip.

### DETAILED DESCRIPTION

In the following further exemplary embodiments of bonding clip, the carrier and the method of manufacturing a bonding clip are described. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a semiconductor component comprising a die, a carrier (like a leadframe or substrate) and a clip, wherein the die or semiconductor chip is connected to the carrier by clip bonding by using the clip and wherein at least the carrier and the clip comprises corresponding or matching guiding structures or elements.

Various exemplary embodiments provide a method of manufacturing a carrier for clip bonding of a die, wherein the method comprises: providing a carrier body comprising a first region configured to be fixed on a clip, and forming a guiding element in the first region, wherein the guiding structure is configured to guide the clip when connecting the carrier and the die.

For example the guiding structure and element may be formed by a recess and projection, respectively or vice versa. Such guiding elements and guiding structures (or guiding features) may provide for a guiding mechanism during the clip placement, e.g. may prevent clip offset, and/or may prevent as well a mismatch or relative turning of the clip with respect to the carrier during or after a reflow step or process. Thus, the guiding features may particularly function as a stopper for turning movements. For example, such an offset may even cause damage to a mold or mold cavity during a later molding step. Thus, it may be possible to reduce rejections or faulty semiconductor packages or components and therefore may increase the yield of a packaging manufacturing process by providing matching guiding features, e.g. guiding structures and/or guiding elements on the carrier and clip and optionally even on the die or chip which is clip bonded to the carrier by the clip.

Optionally, a plurality of guiding structures and/or guiding elements may be formed on the clip and/or carrier, respectively. Thus, it may be possible to further reduce a possibility of faulty offset or turning or (in case the plurality of guiding elements is formed on the carrier) to bond a plurality of clips and respective dies to a single carrier, e.g. in case of a leadframe configured to hold a plurality of dies or chips.

In particular, guiding structures may be formed on a first region of the bonding clip (configured or adapted to be connected or bond to the carrier) and/or may be formed on a second region of the bonding clip (configured or adapted to be connected or bond to a die or chip).

By providing a guiding structure on at least one of the first and the second regions of the clip it may be possible to enable a guiding function during the connecting and in particular also at reflow process. For example, a clip offset may be avoided or at least the possibility of such an offset may be reduced so that a yield of a manufacturing process may be increased.

In particular, the guiding structure may be only formed on the first region or may be only formed on the second region. Alternatively, one guiding structure may be formed on the first region and a second guiding structure may be formed on the second region. Such a guiding element or guiding structure may act as a reference feature during the clip attach bonding, in particular during the placement of the clip and/or die on the carrier.

In the following exemplary embodiments of the bonding clip are described. However, the features and elements described with respect to these embodiments can be combined with exemplary embodiments of the carrier and the methods of manufacturing a clip or a carrier.

According to an exemplary embodiment of the clip the guiding structure is formed by a projection on a surface of the first region.

Alternatively or additionally, the guiding structure may be formed by a projection on a surface of the second region.

According to an exemplary embodiment of the clip the guiding structure is formed by a recess in a surface of the first region.

Alternatively or additionally, the guiding structure may be formed by a recess on a surface of the second region. It should be noted that the recess may even be some form of cut-out, i.e. may extend through the whole thickness of the clip. However, it may also be only some form of blind hole, i.e. may not extend through the whole thickness of the clip.

In particular, the recess or the projection may be formed by an elongated surface structure. However, it should be noted that any shape or form of the recess and/or projection may be used which enable a guiding or reference function during and/or after a placement and/or bonding step or process. For example, the guiding structure may have a pointing, trapezoidal, convex or concave form (inclined sidewalls), which may improve a guiding function during placement. Alternatively, the guiding structure may have substantially perpendicular sidewalls which may reduce a turning probability even further.

According to an exemplary embodiment of the clip the guiding structure is formed by a process selected out of the group consisting of: etching; stamping; plating and cutting.

According to an exemplary embodiment of the clip the clip comprises copper.

According to an exemplary embodiment of the clip the guiding structure has a height in the range of 25 micrometer to 1 millimeter.

In particular, the height may be in the range of 50 micrometer to 500 micrometer, preferably in the range of 100 micrometer to 250 micrometer, e.g. about 125 micrometer or 200 micrometer. It should be mentioned that the term “height” may in particular denote a depth of a recess (in case the guiding structure is formed by a recess) or as an extension the guiding structure extends or projects above surrounding areas of the region (first or second region).

According to an exemplary embodiment of the clip the guiding structure has a height in the range of 25% to 75% of a carrier thickness.

That is, the guiding structure may have a height depending on the carrier it is intended to be used with. In particular, the height may be in the range of 35% to 65% of the thickness of the carrier, preferably in the range of 45% to 55%, e.g. about 50%.

In the following exemplary embodiments of the carrier are described. However, the features and elements described with respect to these embodiments can be combined with exemplary embodiments of the bonding clip, the methods of manufacturing a bonding clip or carrier.

According to an exemplary embodiment the guiding element is formed by one element selected out of the group consisting of: a projection on a surface of the first region; and a recess in a surface of the first region.

According to an exemplary embodiment the carrier is a leadframe.

In particular, the leadframe may be formed of any suitable electrically conductive material like copper, aluminum, for example. Alternatively the carrier may be a substrate configured to receive or hold a chip or die.

According to an exemplary embodiment of the carrier the carrier comprises a plurality of guiding elements.

In particular, each guiding element may be configured to guide a different clip, i.e. the carrier may be configured so that a plurality of chips or dies can be attached to or placed on the carrier. For example, the carrier may be a leadframe comprising a plurality of reception areas each configured to receive a single (or even several) die or chip.

According to an exemplary embodiment of the carrier a thickness of the carrier is in the range of 50 micrometer to 2 millimeter.

In particular, the thickness of the carrier may be in the range of 100 micrometer to 1 millimeter, preferably in the range of 200 micrometer to 500 micrometer, e.g. about 250 micrometer.

In the following exemplary embodiments of the method of manufacturing a bonding clip are described. However, the features and elements described with respect to these embodiments can be combined with exemplary embodiments of the bonding clip, the carrier and the method of manufacturing a carrier.

According to an exemplary embodiment of the method the forming is performed by on process selected out of the group consisting of: etching; stamping; plating; and cutting.

It should be mentioned that of cause different processes may be combined when the guiding structure is formed, e.g. the total forming process may be a combination of stamping and etching, a combination of plating and etching, or the like.

According to an exemplary embodiment of the method the guiding structure is a projection.

In particular, the projection may be formed or generated by depositing additional material at an area or position the guiding structure shall be formed, and/or by (selectively) etching areas surrounding the position the guiding structure shall be formed, and/or by using a stamping tool, e.g. by exerting a force from one side to the clip body at a position opposite to the position where the projection shall be formed so that a projection is formed by deformation or bending.

According to an exemplary embodiment of the method the guiding structure is a recess.

In particular, the projection may be formed or generated by depositing additional material at an area or position surrounding the position the guiding structure shall be formed, and/or by (selectively) etching areas at the position the guiding structure shall be formed, and/or by using a stamping tool and forming the recess at the intended position.

In the following specific embodiments of the bonding clip, the carrier and the methods of manufacturing a bonding clip or carrier will be described in more detail with respect to the figures.

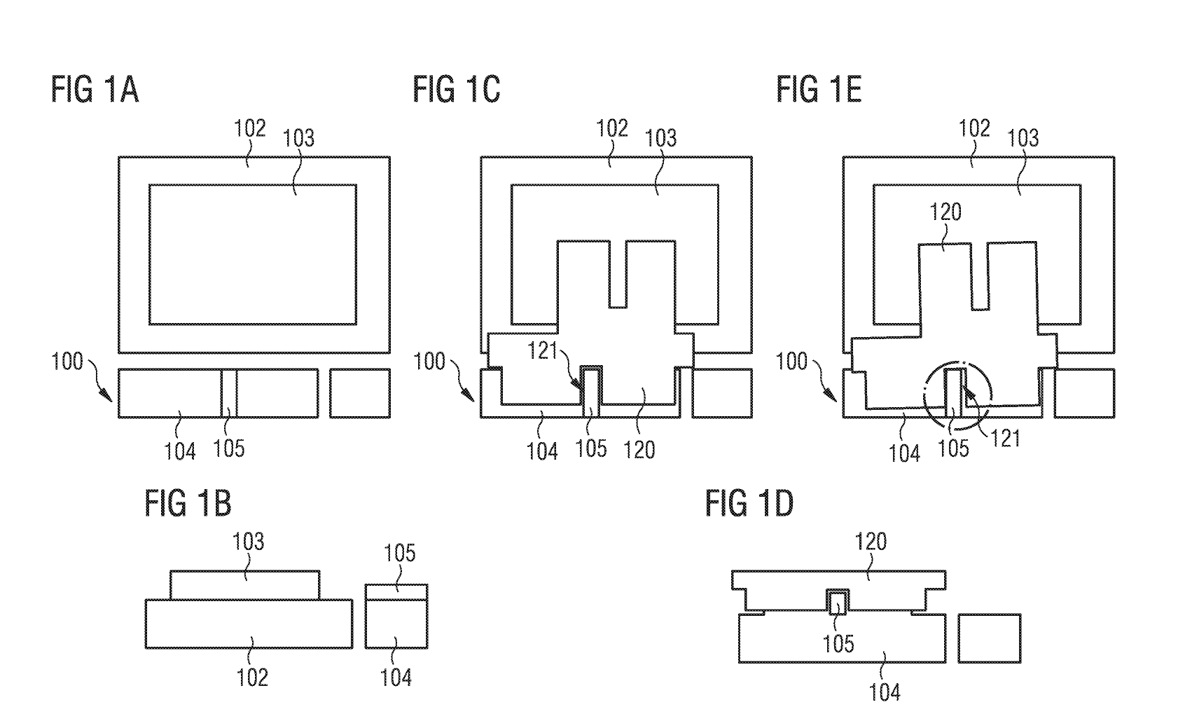

FIGS. 1A to 1E schematically illustrate a semiconductor component in various process steps. In particular, FIG. 1A shows a portion of a carrier 100, like a leadframe or a leadpad, and a die pad 102 on which a chip or die 103 is arranged or placed. The carrier comprises a region 104 which is configured to be contacted by a bonding clip. In this region 104 a guiding element 105 is formed. In the case of FIG. 1A the guiding element 105 is formed by an elongated projection. FIG. 1B shows the arrangement of FIG. 1A in a side view, so that the chip or die 103 and in particular the guiding element 105 can be clearly seen.

FIG. 1C schematically illustrates the arrangement of FIG. 1A having a bonding clip 120 arranged thereon. The bonding clip 120 comprises a guiding structure 121 formed at the bonding clip, which guiding structure 121 corresponds to or matches the guiding element 105. In particular, the guiding structure is formed by a recess or cut-off complementary to the elongated projection 105.

FIG. 1D schematically illustrates a front view of the arrangement or semiconductor component of FIG. 1C. In particular, the matching of the guiding element 105 and the guiding structure 121 can be seen.

FIG. 1E schematically illustrates that the guiding element 105 and guiding structure 121 is substantially prevents a major relative offset or turning of the bonding clip 120 relative to the carrier 100 during placing, bonding and/or after a reflow process. In particular, the guiding element 105 functions as a guiding unit or stopper.

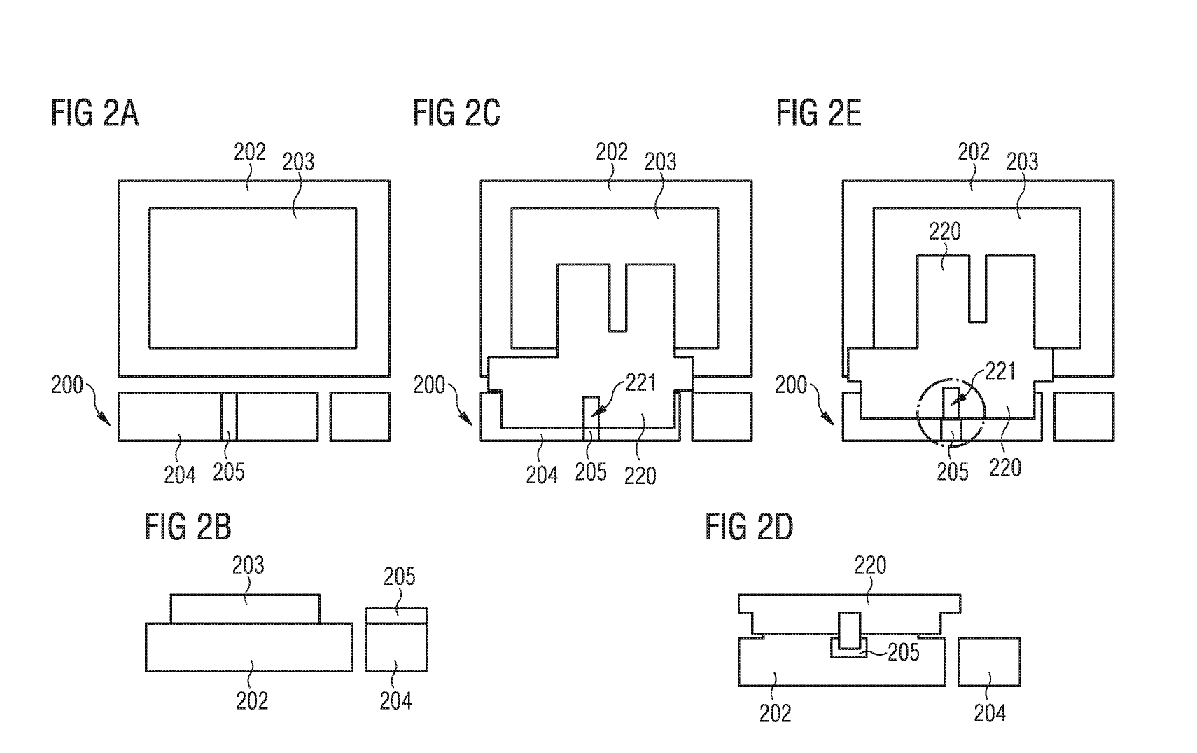

FIGS. 2A to 2E schematically illustrate a semiconductor component in various process steps. In particular, FIG. 2A shows a portion of a carrier 200, like a leadframe or a leadpad, and a die pad 202 on which a chip or die 203 is arranged or placed. The carrier comprises a region 204 which is configured to be contacted by a bonding clip. In this region 204 a guiding element 205 is formed. In the case of FIG. 2A the guiding element 205 is formed by an elongated recess, which may be formed by an etching process, for example. FIG. 2B shows the arrangement of FIG. 2A in a side view, so that the chip or die 203 and in particular the guiding element 205 can be clearly seen.

FIG. 2C schematically illustrates the arrangement of FIG. 2A having a bonding clip 220 arranged thereon. The bonding clip 220 comprises a guiding structure 221 formed at the bonding clip, which guiding structure 221 corresponds to or matches the guiding element 205. In particular, the guiding structure is formed by an elongated projection complementary to the elongated recess 205.

FIG. 2D schematically illustrates a front view of the arrangement or semiconductor component of FIG. 2C. In particular, the matching of the guiding element 205 and the guiding structure 221 can be seen.

FIG. 2E schematically illustrates that the guiding element 205 and guiding structure 221 substantially prevents a major relative offset or turning of the bonding clip 220 relative to the carrier 200 during placing, bonding and/or after a reflow process. In particular, the guiding element 205 functions as a guiding unit or stopper.

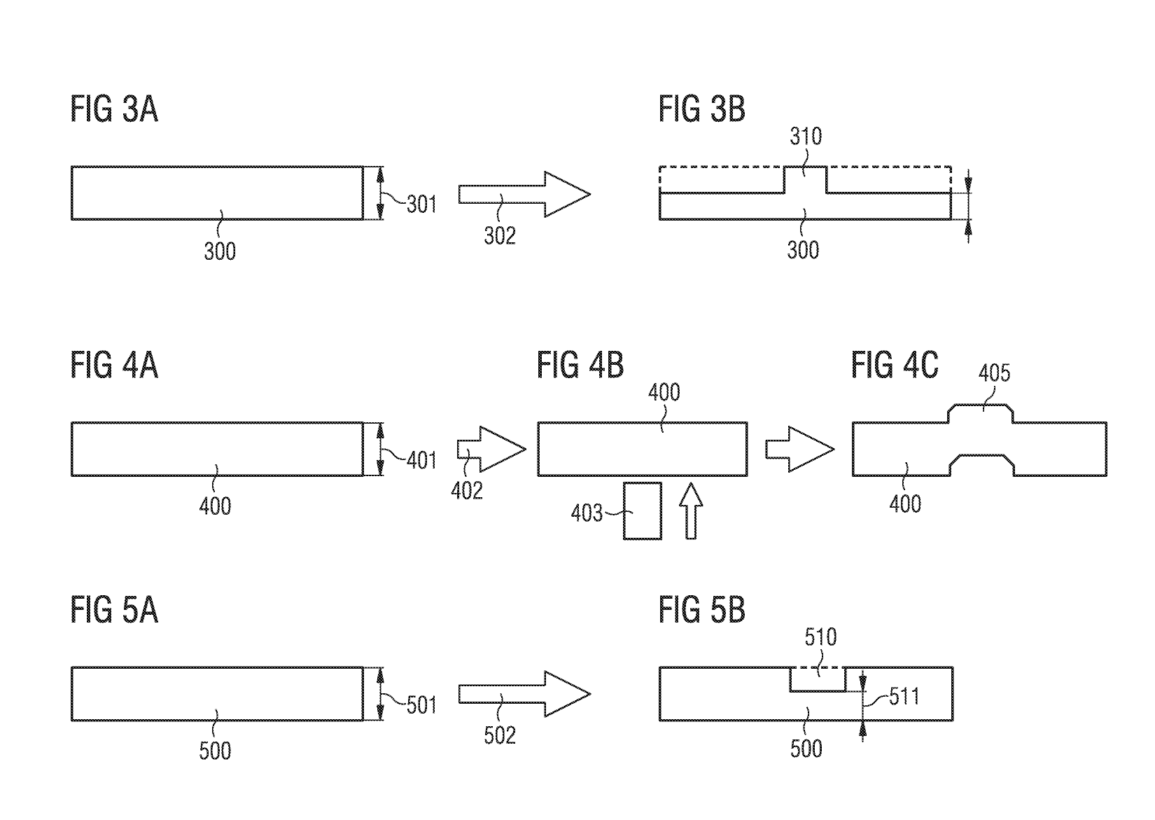

FIGS. 3A to 3B schematically illustrate a method of manufacturing a bonding clip. In particular, FIG. 3A schematically illustrates a leadframe or fused leadpad 300 in a side view. The leadpad 300 having a thickness of 250 micrometer, for example, indicated by arrow 301. In etching process (indicated by arrow 302) the leadpad is structured to form a guiding element, like an elongated projection 310 as indicated in FIG. 3B, by etching out portions of the leadpad 300. After the etching process the guiding element may still have a thickness of 250 micrometer while the other portions of the leadpad 300 may only have a remaining thickness of about 125 micrometer. It should be mentioned that of cause a guiding structure of a bonding clip may be formed by a corresponding etching process.

Furthermore, it should be mentioned that the above only describes some steps of the etching process. However, the whole etching process may comprise several additional steps, like printing before an etching step, followed by a plating step after the etching step. The plating step may comprise a plurality of sub-steps like resist coating, printing, developing, plating, resist remove, washing and drying. After the plating step a cutting step, visual inspection and packaging step may be performed.

FIGS. 4A to 4C schematically illustrate a method of manufacturing a bonding clip. In particular, FIG. 4A schematically illustrates a leadframe or fused leadpad 400 in a side view. The leadpad 400 having a thickness of 250 micrometer, for example, indicated by arrow 401. In a stamping process (indicated by arrow 402) a stamping tool (schematically indicated by a stamping tool 403) is used to expose the leadpad 400 to a pressing or bending force which is indicated by arrow 404. The result of the stamping process is shown in FIG. 4C. In particular, the stamping process forms a guiding element 405 at the upper part or surface of the leadpad 400 while at the same time a recess is formed in the lower part or surface of the leadpad.

It should be mentioned that of cause a guiding structure of a bonding clip may be formed by a corresponding etching process.

Furthermore, it should be mentioned that the above only describes some steps of the stamping process. However, the whole stamping process may comprise several additional steps, like printing before a stamping step, followed by a plating step after the stamping step. The plating step may comprise a plurality of sub-steps like resist coating, printing, developing, plating, resist remove, washing and drying. After the plating step a cutting step, visual inspection and packaging step may be performed.

FIGS. 5A to 5B schematically illustrate a method of manufacturing a bonding clip. In particular, FIG. 5A schematically illustrates a leadframe or fused leadpad 500 in a side view. The leadpad 500 having a thickness of 250 micrometer, for example, indicated by arrow 501. In etching process (indicated by arrow 502) the leadpad is structured to form a guiding element, like an elongated recess 510 as indicated in FIG. 5B, by etching out a portion corresponding to the intended recess. After the etching process the guiding element may only have a thickness of 125 micrometer (indicated by arrow 511) while the other portions of the leadpad 500 may still have a remaining thickness of about 250 micrometer. It should be mentioned that of cause a guiding structure of a bonding clip may be formed by a corresponding etching process.

It should also be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A clip for clip bonding of a die to a carrier, the clip comprising:
a clip body comprising a first region configured to be fixed on a carrier and a second region configured to be fixed to a die,
wherein at least one of the first region and the second region comprises a guiding structure configured to guide the clip when connecting the carrier and the die.

2. The clip according to claim 1, wherein the guiding structure is formed by a projection on a surface of the first region.

3. The clip according to claim 1, wherein the guiding structure is formed by a recess in a surface of the first region.

4. The clip according to claim 1, wherein the guiding structure is formed by a process selected out of the group consisting of:
etching;
stamping;
plating; and
cutting.

5. The clip according to claim 1, wherein the clip comprises copper.

6. The clip according to claim 1, wherein the guiding structure has a height in the range of 25 micrometer to 1 millimeter.

7. The clip according to claim 1, wherein the guiding structure has a height in the range of 25% to 75% of a carrier thickness.

8. A carrier for a semiconductor component, the carrier comprising:
a carrier body comprising a first region configured to be fixed to a clip,
wherein the first region comprises a guiding element configured to guide the clip when connecting the clip to the carrier.

9. The carrier according to claim 8, wherein the guiding element is formed by one element selected out of the group consisting of:
a projection on a surface of the first region; and
a recess in a surface of the first region.

10. The carrier according to claim 8, wherein the carrier is a leadframe.

11. The carrier according to claim 8, wherein the carrier comprises a plurality of guiding elements.

12. The carrier according to claim 8, wherein a thickness of the carrier is in the range of 50 micrometer to 2 millimeter.

13. A method of manufacturing a bonding clip, wherein the method comprises:
providing a clip body comprising a first region configured to be fixed on a carrier and a second region configured to be fixed to a die, and
forming a guiding structure in at least one of the first region and the second region, wherein the guiding structure is configured to guide the clip when connecting the carrier and the die.

14. The method according to claim 13, wherein the forming is performed by on process selected out of the group consisting of:
etching;
stamping;
depositing; and
polishing.

15. The method according to claim 13, wherein the guiding structure is a projection.

16. The method according to claim 13, wherein the guiding structure is a recess.
